(19) United States
(12) Patent Application Publication
(10) Pub. No.: US 2009/0085585 A1
(43) Pub. Date: Apr. 2, 2009

(54) APPARATUS, SYSTEM, AND ASSOCIATED METHOD FOR MONITORING SURFACE CORROSION

(75) Inventors: Jilai Lu, Shanghai (CN); Weiguo Chen, Shanghai (CN); Brian Walter Lasiuk, Waukesha, WI (US); Yu Zhang, Shanghai (CN)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: GENERAL ELECTRIC COMPANY, Schenectady, NY (US)

(21) Appl. No.: 11/871,398

(22) Filed: Oct. 12, 2007

(30) Foreign Application Priority Data
Sep. 30, 2007 (CN) 200710164131.3

(51) Int. Cl. G01R 27/02; G01B 7/06

(52) U.S. Cl. 324/700; 702/38

(57) ABSTRACT

An article includes an electrically conductive corrodible element; a device that can inject electricity at a plurality of operation frequencies into the corrodible element; and a measurement apparatus operable to measuring impedance of the electrically conductive corrodible element under various operation frequencies.

### BACKGROUND

1. Technical Field

The invention includes embodiments that relate to a method for monitoring and estimating surface corrosion. The invention includes embodiments that relate to an apparatus for monitoring and estimating surface corrosion. The invention includes embodiments that relate to a system for monitoring and estimating surface corrosion.

2. Discussion of Art

A corrosion monitoring apparatus is useful in an industrial system having corrodable parts. Because corrosion is generally undesirable, corrosion prevention methods may be used. One corrosion prevention method involves the addition of a corrosion inhibitor into a corrosive fluid that contacts a corrodible part. In a cooling system, for example, chemical corrosion inhibitor dosages may suppress corrosion. There is some range between a safe minimum dosage level and an actual minimum dosage level. If a real-time corrosion monitoring apparatus is available, the inhibitor feed rate would be continuously adjusted according to a real-time corrosion monitoring feedback to move the actual dosage rate closer to the lower actual minimum dosage rate.

Existing methods for corrosion detection include: corrosion coupons, electrical resistance (ER), inductive resistance (IR), linear polarization resistance (LPR), electrochemical impedance spectroscopy (EIS), Harmonic Analysis, Electrochemical Noise (EN), Zero Resistance Ammetry (ZRA), potentiodynamic polarization, thin layer activation (TLA), electrical field signature method (EFSM), acoustic emission (AE), corrosion potential, hydrogen probes, and chemical analyses. ER and IR methods measure the electric property of a corrosion sample to estimate the amount of corrosion. Commercial sensor elements that utilized ER and IR methods may take the form of plates, tubes, or wires. The sensors sensitivity can be increased by a reduction in the elements thickness. However, the sensor element lifetime diminishes significantly as the sensor element's thickness is reduced. Other methods including EN, ZRA, potentiodynamic polarization, TLA, EFSM, AE, corrosion potential, hydrogen probes, and chemical analyses utilize indirect evidences to detect corrosion, which tend to be affected by factors other than corrosion.

It may be desirable to have an apparatus or system with properties and characteristics that differ from those properties of currently available apparatus or system. It may be desirable to have a corrosion detection or corrosion monitoring method that differs from those methods currently available.

### BRIEF DESCRIPTION

In one embodiment, an article includes an electrically conductive corrodible element; a device that can inject electricity at a plurality of various operation frequencies into the corrodible element; and a measurement apparatus operable to measuring impedance of the electrically conductive corrodible element under the plurality of various operation frequencies.

In one embodiment, a method includes measuring impedances under various operation frequencies, wherein impedances measured under high frequencies reflect localized corrosion features and impedances measured under low frequencies reflect general corrosion features.

In one embodiment, a method includes monitoring localized and uniform corrosion on an electrically conductive corrodible surface by: determining a finite-element-model (FEM) for relationship between corrosion and impedance profile over a frequency range; injecting electricity at a plurality of operation frequencies into the corrodible surface; measuring the respective impedance of the injected electricity at each of the plurality of operation frequencies to form an impedance profile of the corrodible surface; and comparing a change in the impedance profile from the FEM model estimating localized and uniform corrosion.

### BRIEF DESCRIPTION OF DRAWINGS

FIG. 1 schematically illustrates a detecting apparatus for measurement of surface corrosion according to an exemplary embodiment of the invention;

FIG. 2 illustrates an impedance profile of a coupon and skin depths of electrical current flowing through the coupon under different operation frequencies;

FIG. 3 schematically illustrates a cross-sectional view of the coupon with a skin-depth of electrical current under one exemplary operation frequency;

FIG. 4 shows a comparison of impedances of the coupon with and without a pitting, under increasing operation frequencies;

FIG. 5 shows a sectional view of the coupon, wherein a skin depth of electrical current is substantially equal to half of the height of the coupon.

### DETAILED DESCRIPTION

The invention includes embodiments that relate to a method for monitoring and estimating surface corrosion. The invention includes embodiments that relate to an apparatus for monitoring and estimating surface corrosion. The invention includes embodiments that relate to a system for monitoring and estimating surface corrosion.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable, or suitable.

General (or uniform) corrosion refers to the relatively uniform reduction of thickness over the surface of a corroding material. General corrosion damages and removes metal mass, which changes the geometry, i.e., thickness of the surface, and causes a degradation or depletion of original material. General corrosion compromises the structural rigidity and integrity of a pipe or vessel. On the other hand, localized corrosion refers to that is widespread or limited to only a few areas of the target system, but is relatively non-uniform and occurs on a relatively small scale. Exemplary localized corrosion can include, but is not limited to, pitting, environmental stress cracking (ESC), (hydrogen) embrittlement, and the like, as well as combinations thereof.

Skin effect is a phenomenon that an alternating current (AC) flows mostly near an outer surface of a solid electrical conductor, such as a metal wire. At low frequencies, the current travels through an entire cross-section of the conductor. As the frequency increases, the current traveling through the conductor approximately concentrates in a peripheral sheet of thickness of the electrical conductor. The thickness (“skin depth δ” herein after) equation (equation 1-1) is:

$$δ = \sqrt{\frac{ρ}{π * f * μ}} \qquad 1 \text{-} 1$$

wherein f is the transmission frequency of the AC current; ρ is “resistivity” which is only related to the material of the conductor; and μ is “permeability of vacuum”, which is a constant parameter, μ=3.192*10⁻⁸ weber/amp.in. Therefore, for one solid electrical conductor, the skin depth δ is only related to and scales as the square root of the operation frequency.

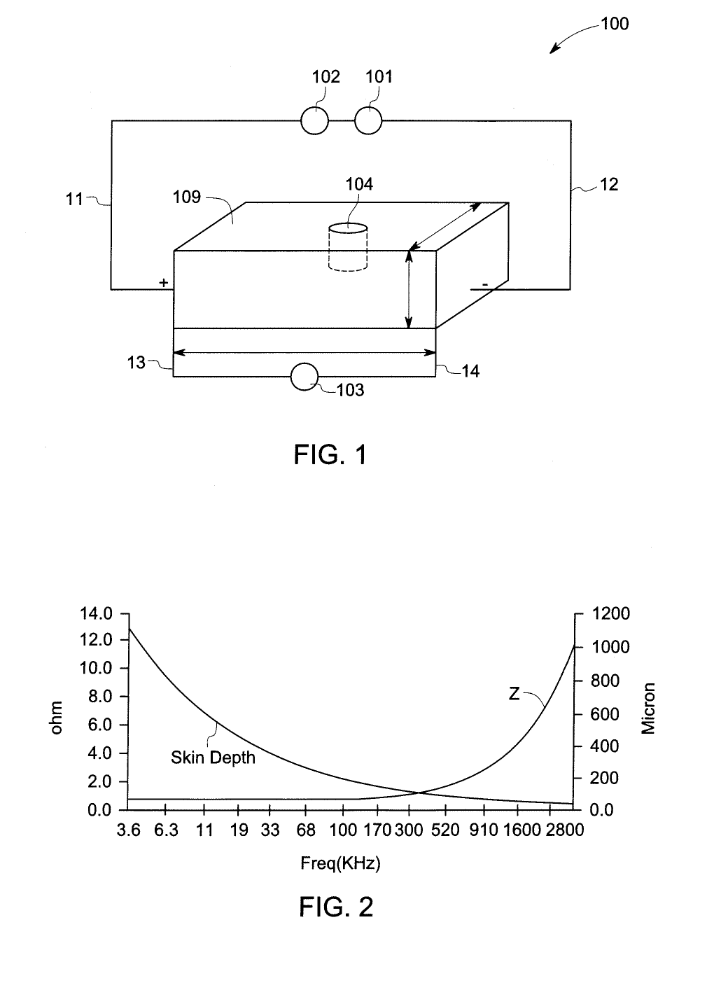

A detecting apparatus 100 is shown in FIG. 1. The detecting apparatus 100 may provide real-time detection of a metal surface corrosion utilizing the skin effect phenomenon. The metal surface corrosion may be in, for example, a fluid transmission pipeline. The detecting apparatus 100 includes a coupon 1, a power device 101 for injecting electrical power to the coupon 1, and a measurement apparatus for real-time detection of impedances Z of the coupon 1. The coupon 1 is made from substantially the same conductive material as of a subject that is undergoing corrosion. In the case of the fluid transmission pipeline, the coupon 1 is made from the same material as of an inner surface of the pipeline. During measurement, the coupon 1 is disposed in the pipeline, so that the coupon 1 and the inner surface of the pipeline are subjected to substantially the same corrosive physical environment. In one embodiment, as shown in FIG. 1, only an upper surface 109 of the coupon 1 is exposed to the corrosive environment, and the other five surfaces of the coupon 1 are sealed and avoided from being corroded.

In certain embodiments, the coupon 1 is a strip made from copper with a rectangular cross section, which has a length of “a”, a width of “b”, and a height of “h”. In other embodiments, the cross section of the coupon 1 can also be in any of the shapes of a circular, an ellipse and etc. One exemplary coupon 1 is made from copper, with a size of a=50 mm, b=10 mm, and h=1 mm.

In one embodiment, the measurement apparatus for real-time measurement of impedances Z of the coupon 1 is a four-wire measurement system. As shown in FIG. 1, four sensor leads, or conductive members, including a positive current lead 11, a negative current lead 12, a positive voltage lead 13, and a negative voltage lead 14, are connected with the coupon 1. The positive and negative current leads 11, 12 respectivley connect with positive and negative current terminals of the power device 101 and an ammeter 102 in series. The power device 101 can be a current source. The positive and negative voltage leads 13, 14 are respectivley connected to positive and negative voltage terminals of a voltage meter 103. The power device 101 sents alternating currents (AC) through the coupon 1 with different operation frequencies. In the examplary embodiment, the power device 101 sends increasing frequencies to the coupon 1. The ammeter 102 and the voltage meter 103 respectively measure real-time current and voltage of the coupon 1, and thus real-time impedancs of the coupon 1 is calculated by Ohm's Law. The four-wire measurement output virtually eliminates any uncertainties in voltage drop or impedance change across the leads 11-14, and makes this arrangement especially utilitarian in operation of the ammeter 102 and voltage meter 103 a significant distance from the coupon 1 and the corrosive environment.

The impedance Z of the coupon 1 is subject to the following equation (equation 1-2):

$$Z = R + j ( ω {L}_{s} - \frac{1}{ω {C}_{s}} ) \qquad ( equation 1 \text{-} 2 )$$

Wherein R is circuit resistance, Lₛ is circuit inductance, Cₛ is circuit capacitance, and ω is angular frequency.

Impedance Z is a measurement of opposition of a conductor to the AC currents, which includes resistance R and reactance. Resistance R is due to electrons in a conductor colliding with the ionic lattice of the conductor and means that electrical energy is converted into heat. Different materials have different resistaivities. Reactance, however, is a measurement of the opposition to AC electricity due to capacitance Cₛ and inductance Lₛ which varie with frequency. Practically, size of the coupon 1 is much smaller than wavelength of the current from the power device 101, and thus inductacne Ls and capacitance Cs have very little effect to the impedance Z. In the following analysis and description, impact of the inductance and capacitance to the impedance is ignored, and resistance R is deemed substantially the same as the impedance Z.

By way of example, consider the coupon 1 has continuous general corrosion with loss to the height h, and a localized pitting 104 occurs in the upper surface 109 of the coupon 1. Methods of real-time detection of the general corrosion and the pitting 104, by the detecting apparatus 100, are discussed in detail below.

### General Corrosion

As discussed, due to the skin effect phenomenon, at high AC frequencies, the current skin depth δ decays as an electromagnetic wave attempts to penetrate the metal. Thus, only the skin portion of the coupon 1 (that has been penetrated by the current) actually contributes to the impedance and the observed impedance is frequently referred to as the “AC impedance” of the coupon 1.

While the current flow surface region defined by the skin effect produced at a given frequency is bounded by an decaying surface, the AC impedance may be reasonably computed by assuming that the total current in the conductor is uniformly distributed over a thickness of one skin depth. This simplification of sequestered sample volume geometry, as provided by equation 1.1, facilitates calculation of the AC impedance within the skin depth region at a given frequency, and was employed with the detecting apparatus 100 and method of the present invention.

Referring to FIG. 2, an impedance profile under increasing frequencies and the corresponding skin depths are illustrated. At low frequencies, the skin depths are no less than half of the height h of the coupon 1, thus the AC current flows through entire cross-section of the coupon 1. When applying the standard equation for resistance R (equation 1-2):

$$R = ρ * \frac{L}{S} \qquad 1 \text{-} 2$$

wherein ρ is the material electrical resistivity, L is the wire length a of the coupon, and S is the cross section penetrated by the current and defined by the skin depth δ. Therefore, at low frequencies, L is substantially the same with the length a of the coupon 1, and S is the total cross section of the coupon 1, i.e. S=b*h. Thus, AC resistance R of the coupon 1 is substantially constant under low operation frequencies.

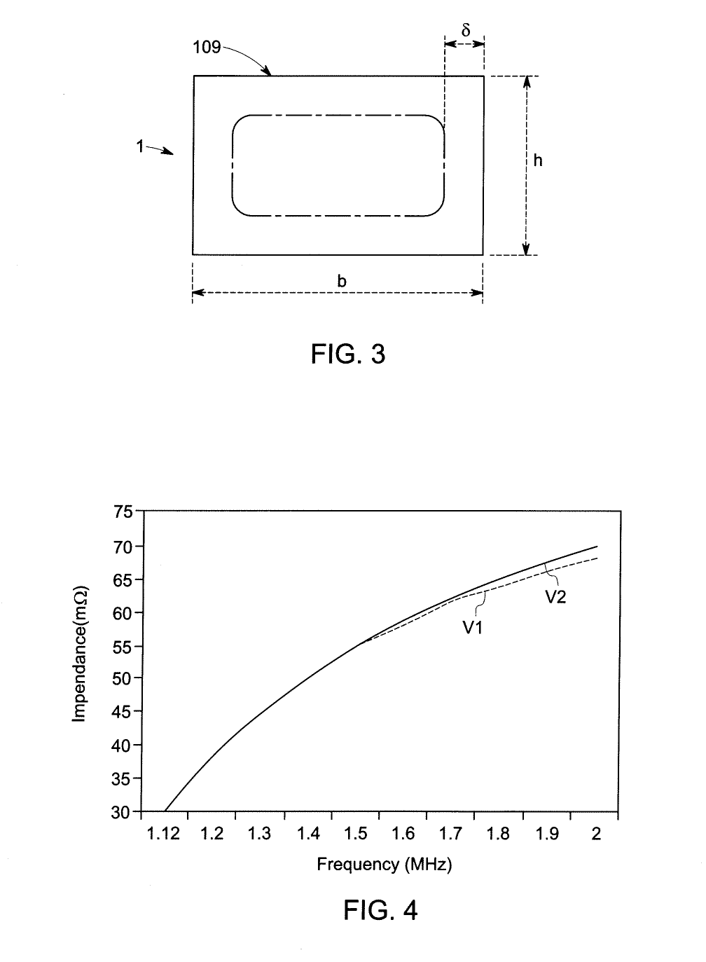

As the operation frequency increases, when the skin depth is less than half of the height h, the corresponding frequency is called “first critical frequency f₀”, the coupon 1 may be considered as a thin hollow conducting tube of length “a” and a wall thickness “δ”, as shown in FIG. 3. The AC current is considered to be uniformly distributed within the skin depth region. When applying the standard equation for wire resistance:

$$R = ρ * \frac{L}{S} = ρ * \frac{L}{2 δ ( b + h - 2 δ )} , \qquad 1 \text{-} 3$$

wherein the effective cross section S of the AC current is smaller than the total cross section of the coupon 1. Thus the resistance R (impedance Z) of coupon 1 has a sharp increase at the first critical frequency f₀, as shown in FIG. 2.

Therefore, a general corrosion of the coupon 1 can be detected by measuring real-time impedances of the coupon 1 under increasing operation frequencies, and the measured impedances are shaped into an impedance profile. On the impedance profile, where there is a sharp increase of the impedance, the corresponding frequency is the first critical frequency f₀, where the skin depth δ is substantially the same as half of the height h of the coupon 1. Then the skin depth δ, i.e. half of the height h of the coupon, can be calculated by equation 1-1.

$$h \approx 2 δ = 2 \sqrt{\frac{ρ}{π * {f}_{0} * μ}}$$

In certain embodiments, a second derivative of the impedence profile according to equation 1-3 may be used for prediction of the presence of the sharp increase of the impedance profile of FIG. 2. At low frequencies, f≦f₀, the mpedance is a constant value, and substantially equal to ρ*L/S, then second derivation of the AC impedance is zero; when the freqency is more than the first critical frequency f₀, the impedance is a quadratic function of the skin depth δ, and second derivation of the impedance is a constant value but not sero. Therefore, the presence of the first critical frequency f₀ can be observed on a second deviation profile.

### Localized Corrosion

As shown in FIG. 4, curve v1 is the resistance R (impedance Z) of the coupon 1, without a pitting 104, under increasing frequencies. Curve v2 is the resitance R (impedance Z) of the examplary coupon 1, with a pitting 104, under increasing operation frequencies. At low operation frequencies, curves v1 and v2 substantially overlap, i.e., the pitting 104 has very little effect to the AC impedance. The curve v2 has a sharp increase comparing with the curve v1 when the operation frequency is 1.6 MHZ, i.e. the pitting 104 begins to affect changes of the AC impedance of the coupon 1 when frequency is higher than 1.6 MHZ.

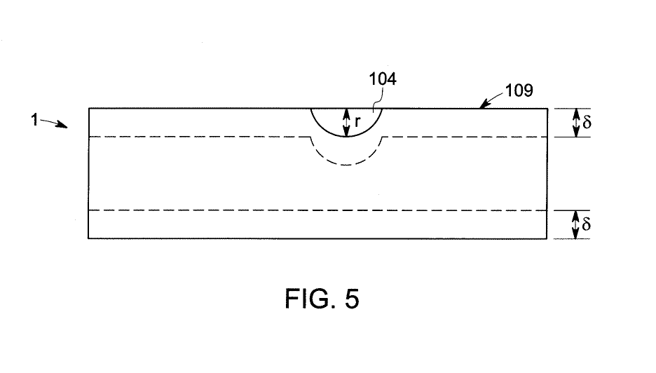

According to the standard equation for wire resistance (equation 1-2), once the skin depth δ is more than half of the height h of the coupon 1, as the frequency increases further, the effective cross section of the coupon 1 is less, but the effective lengh L has substantially no changes. Therefore the resistance (impedance) of the coupon 1 is only related to the skin depth, which is determined by the operation frequencies. The pitting 104 has little effect to the AC resistance (impedance). When the skin depth is approaching depth r of the pitting 104 (hereinafter pitting depth r), the AC current flows through a convex path around the pitting 104 as shown in FIG. 5. Therefore, the effective length L in the fundamental equation of resistance (equation 1-2) changes due as the frequency increases even further, as shown in FIG. 4. Pitting depth r contributes to changes of the AC resistance (impedance) of the coupon 1. Therefore, where the curve v2 has a sharp increase comparing with curve 1, the corresponding operation frequency is a “second critical frequency f1”, 1.5 MHZ in FIG. 3, and the corresonding skin depth δ is substantially equal to the pitting depth. The pitting depth can be calculated by:

$$r \approx δ \sqrt{\frac{ρ}{π * {f}_{1} * μ}}$$

In fact, when the skin depth is close to the pitting depth r, the AC current has already flowed through the convex bottom portion of the pitting 104 and affect changes of the AC impedance. Therefore, it is to be understandable that the pitting depth r is not identical to δ, but the error therebetween is acceptable in real detection of surface corrosion. Moreover, since the skin depth δ measured by this simplified method is greater than the real pitting depth r, it is advantageous to detect the pitting much earlier.

Accurate corrosion depth of the pitting 104 can be calculated by using a Finite-Element-Model (FEM) method, according to the relationship between the AC impedance of the coupon 1 and the increasing frequencies. Examples of commercially available FEM software include ANSYS®, available from Swanson Analysis Systems, Inc., ADINA®, available from R & D, Inc., and ABAQUS®, available from Hibbitt, Karisson, & Sorenson, Inc.

In certain embodiments, the power device 101 sends increasing frequencies, in a linear or logarithmic manner, to the coupon 1 for detecting the general corrosion and localized corrosion. The low frequencies of the increasing frequencies reflect general corrosion features, and the high frequencies of the increasing frequencies reflect localized corrosion features. The increasing frequencies are selected according to material and the height h of the corrodible conductive element. In certain embodiments, the skin depth δ at a lowest frequency is higher than half of the height h of the coupon 1, while the skin depth δ at a highest frequency is smaller than tenth of the height h of the coupon 1. In certain embodiments, the power device continuously and repeatedly sends the increasing frequencies to the coupon 1. In alternate embodiments, the power device 101 repeatedly sends the increasing frequencies to the coupon 1 for a preset time, for example 10 seconds, then stops for processing and estimating the general and localized corrosion features.

The embodiments described herein are examples of articles, systems and methods having elements corresponding to the elements of the invention recited in the claims. This written description may enable those of ordinary skill in the art to make and use embodiments having alternative elements that likewise correspond to the elements of the invention recited in the claims. The scope of the invention thus includes articles, systems and methods that do not differ from the literal language of the claims, and further includes other articles, systems and methods with insubstantial differences from the literal language of the claims. While only certain features and embodiments have been illustrated and described herein, many modifications and changes may occur to one of ordinary skill in the relevant art. The appended claims cover all such modifications and changes.

1. An article, comprising:
an electrically conductive corrodible element;
a device that can inject electricity at a plurality of various operation frequencies into the corrodible element; and
a measurement apparatus operable to measuring impedances of the electrically conductive corrodible element under said plurality of various operation frequencies.

2. The article according to claim 1, wherein the measurement apparatus is a four-wire measurement apparatus.

3. The article according to claim 1, wherein the electrically conductive corrodible element has a rectangular cross section.

4. The article according to claim 1, wherein the electrically conductive corrodible element has a cross section in the shape of an ellipse.

5. The article according to claim 1, wherein the electrically conductive corrodible element has a circular cross section.

6. The article according to claim 1, further including a controller/logic device that takes the signal from the measurement apparatus and compares against a known model to estimate the type and amount of the corrosion on the surface of the corrodible element.

7. A system that includes pipes and corrosive fluid in contact with the article described above.

8. The article according to claim 7, wherein only an external surface of the electrically conductive corrodible element is partially exposed to the corrosive fluid.

9. A method, comprising: measuring impedances of a corrodible conductive element under various operation frequencies, wherein impedances measured under high frequencies reflect localized corrosion features and impedences measured under low frequencies reflect general corrosion features.

10. The method according to claim 9, wherein both the localized corrosion situation and the general corrosion situation are measured employing a skin effect phenomenon.

11. The method according to claim 10, further including observing the impedances measured under different frequencies, where there is sharp increase of the impedance, the corresonding skin depth is substantially the same with half of a height of the corrodible conductive element.

12. The method according to claim 10, further including comparing the impedances meausred with reference impedances of the same conductor without a localized corrosion, so as to estimate the localized corrosion.

13. The method according to claim 10, wherein measuring impedances under various operation frequencies includes injecting an electrical current of increasing frequencies to the corrodible conductive element.

14. The method according to claim 10, wherein measuring impedances of a corrodible conductive element under various operation frequencies including selecting the various freqencies according to material and a height of the corrodible conductive element.

15. The method according to claim 14, wherein the low frequencies reflecting general corrosion features is selected as that, the skin depth at a lowest frequency is higher than half of the height of the corrodible conductive element.

16. The method according to claim 14, wherein the high frequencies reflecting localized corrosion features is selected as that, the skin depth at a highest frequency is no more than ten percent of the height of the corrodible conductive element.

17. A method, comprising:
monitoring localized and uniform corrosion on an electrically conductive corrodible surface by:
determining a finite-element-model (FEM) for relationship between corrosion and impedance profile over a frequency range;
injecting electricity at a plurality of operation frequencies into the corrodible surface;
measuring the respective impedance of the injected electricity at each of the plurality of operation frequencies to form an impedance profile of the corrodible surface; and
comparing a change in the impedance profile from the FEM model estimating localized and uniform corrosion.
